(19) United States
(12) Patent Application Publication
(10) Pub. No.: US 2010/0234074 A1
(43) Pub. Date: Sep. 16, 2010

(54) KEYPAD EMULATION

(75) Inventor: Turo Keski-Jaskari, Vantaa (FI)

Correspondence Address: Nokia, Inc., 6021 Connection Drive, MS 2-5-520, Irving, TX, 75039, US

(73) Assignee: NOKIA CORPORATION, Espoo (FI)

(21) Appl. No.: 12/444,013

(22) PCT Filed: Oct. 2, 2006
(86) PCT No.: PCT/US2006/038351

§ 371 Date: Jun. 4, 2010

(51) Int. Cl. H03M 11/00; G09G 5/00; H04W 88/02

(52) U.S. Cl. 455/566; 341/20; 345/156

(57) ABSTRACT

A telephone keypad (10) emulation system for emulating data entry of a telephone keypad (10). The telephone keypad emulation system includes a first selector device (30) and a second selector device (32). The first selector device (30) has at least nine position settings (12) generally arranged in three rows (34, 36, 38) and three columns (40, 42, 44). The second selector device (32) includes a selection actuator adapted to be actuated by a user. The second selector device (32) is spaced from the first selector device (30). In a first mode of operation, a middle one of the position settings of the first selector device (30) has a number “5” as a selectable value. The selectable value of the position settings of the first selector device (30) is only selected when the selection actuator of the second selector device (32) is actuated by the user while the first selector device (30) is at that position setting.

### BACKGROUND OF THE INVENTION

1. Field of the Invention

The invention relates to data entry and, more particularly, to imitating data entry of a telephone keypad.

2. Brief Description of Prior Developments

FIG. 1 shows an example of an ITU-T (International Telecommunication Union-Telecommunication Standardization Sector) keypad 10 for phone dialing. An ITU-T keypad has a keypad layout utilizing twelve keys 12. The ITU-T keypad 10 associates letters of the alphabet with the numbers on the keys 12 of the keypad. By example, the number “2” key carries the letters ABC, the number “3” key carries the letters DEF, etc., as is well known. Other types of letter to number arrangements used in key layouts include those disclosed in U.S. Patent Application Publication No. 2006/0103623 which is hereby incorporated by reference in its entirety.

Many telephone and multifunction devices use a touch screen and a graphical user interface (GUI) to present a virtual ITU-T (International Telecommunication Union-Telecommunication Standardization Sector) keypad for phone dialing. In this case such devices do not have physical keys for dialing a phone number. Touch screen devices may also employ virtual keyboards and/or handwriting recognition for text entry.

There is normally a 12-button numerical keypad or virtual 12-button numerical keypad in almost every mobile phone in the market. Space is reserved on the phone for the keypad or virtual keypad accordingly. However, it is foreseen that this will not be the case with all game and multimedia devices of the future, nor with wrist watch phones or pen phones. When the familiar keypad is gone, other methods for text input are needed.

Another problem is that most of the people using phones today are used to writing text using the keypad, and the learning curve for anything new is long. New data entry devices needing too much learning may drive away some potential customers.

There are virtual keypads and keyboards on touch screens. However, they have no tactile feedback, and letters may be too small for rapid writing. They also may require use of a stylus, and are practically always require two hands to enter data.

U.S. Pat. No. 6,173,194 and EP Patent Application No. 02396184 disclose some other types of data entry devices. There are also other types of joystick or roller-like devices used for data entry. Characteristic for these devices is that the user has to press or turn the device to one of the mapped positions to select the desired number. To make this usable in reality, the device cannot be very small, and it has to have excellent response and boast high quality, to enable the user to always “hit” the correct direction at the first time from the multitude of possibilities. Otherwise, at first the user easily gets a wrong character and maybe after that the correct one. Multiple successful presses in a row towards the same direction can be close to impossible with this kind of setup.

There is a desire for a new type of data entry system, and method which can emulate a telephone keypad for ease of learning and for use in smaller types of portable electronic devices.

### SUMMARY OF THE INVENTION

In accordance with one aspect of the invention, a telephone keypad emulation system is provided for emulating data entry of a telephone keypad. The telephone keypad emulation system includes a first selector device and a second selector device. The first selector device has at least nine position settings generally arranged in three rows and three columns. The second selector device includes a selection actuator adapted to be actuated by a user. The second selector device is spaced from the first selector device. In a first mode of operation, a middle one of the position settings of the first selector device has a number “5” as a selectable value. The selectable value of the position settings of the first selector device is only selected when the selection actuator of the second selector device is actuated by the user while the first selector device is at that position setting.

In accordance with another aspect of the invention, a method of emulating data entry of a telephone keypad with a directional position sensor is provided comprising moving the directional position sensor to one of nine settings, wherein the nine setting are generally arranged in three row and three columns; and actuating a selection actuator by a user to select a data value corresponding to the setting of the directional position sensor. The selection actuator is spaced from the directional position sensor. In a first mode of operation a middle one of the nine settings comprises a number “5” as its data value.

In accordance with another aspect of the invention, a data entry system for a portable electronic device is provided comprising a selector positioning device having at least nine settings; and a selector actuator spaced from the selector positioning device and adapted to be actuated by a user to select a data value corresponding to a setting of the selector positioning device. In a first mode of operation, a middle one of the settings comprises the data value of “5”, two of the settings oppositely lateral to the middle setting comprises the data values of “4” and “6” respectively, three of the settings upward from the middle setting comprise the data values of “1”, “2” and “3” respectively, and three of the settings downward from the middle setting comprise data values of “7”, “8” and “9” respectively.

### BRIEF DESCRIPTION OF THE DRAWINGS

The foregoing aspects and other features of the invention are explained in the following description, taken in connection with the accompanying drawings, wherein:

FIG. 1 is a diagram showing a conventional telephone keypad arrangement;

FIG. 2 is a front view of a portable, hand-held device comprising features of the invention;

FIG. 3 is a diagram showing positions settings for the first selector device used in the hand-held device shown in FIG. 2;

FIG. 4 is a perspective view of an alternate embodiment of the device shown in FIG. 2;

FIG. 5 is a perspective view of another alternate embodiment of the device shown in FIG. 2;

FIG. 6 is a perspective view of another alternate embodiment of the device shown in FIG. 2;

FIG. 7 is a flow diagram illustrating steps of a method used with the invention;

FIG. 8 is a diagram illustrating some components of the device shown in FIG. 2.

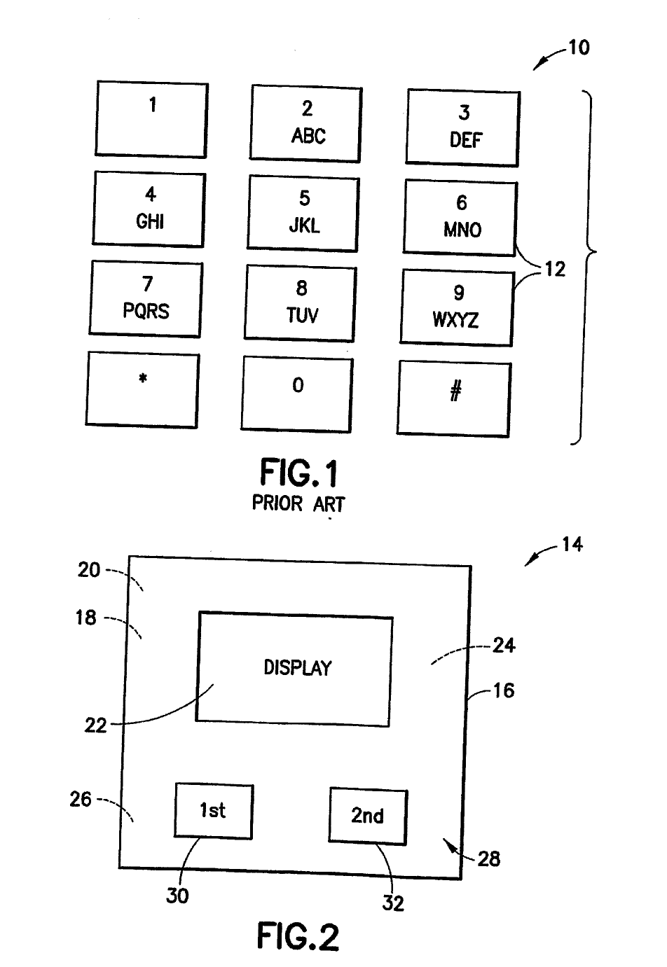

### DETAILED DESCRIPTION OF THE PREFERRED EMBODIMENT

Referring to FIG. 2, there is shown a front view of a portable electronic device 14 incorporating features of the invention. Although the invention will be described with reference to the exemplary embodiments shown in the drawings, it should be understood that the invention can be embodied in many alternate forms of embodiments. In addition, any suitable size, shape or type of elements or materials could be used.

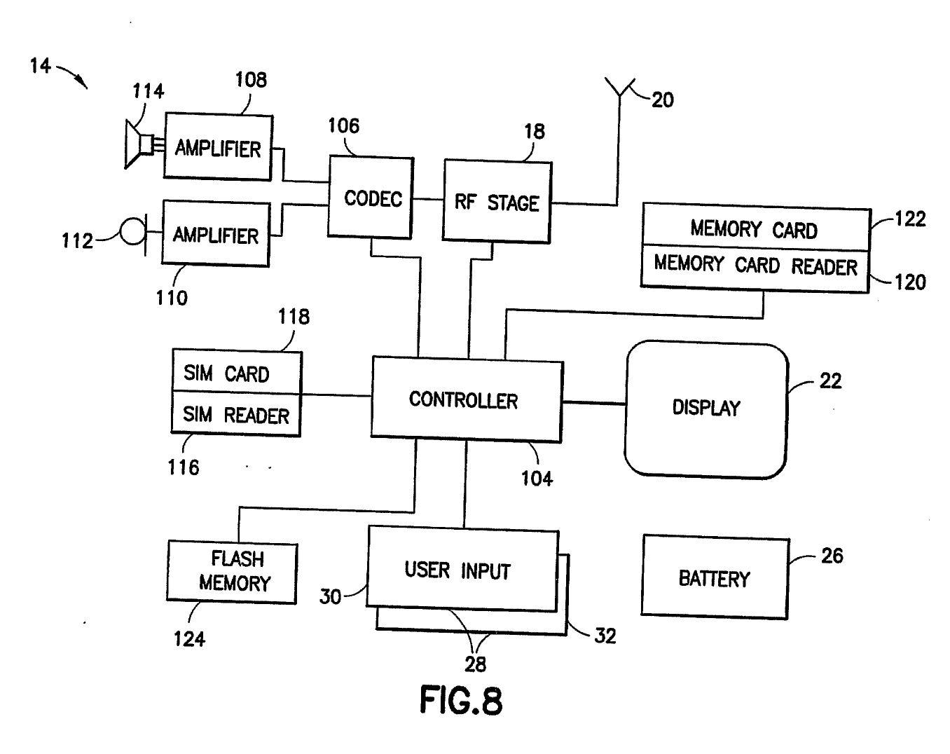

The device 14 is a mobile telephone. However, in alternate embodiments, the device 14 could comprise any suitable portable electronic device, such as a gaming device, or a PDA, or a wearable device, or a pen phone, or a communicator, for example. Referring also to FIG. 8, the phone 14 generally comprises a housing 16, a transceiver 18, an antenna 20, a display 22, internal circuitry 24, a battery 26, and a user input 28. However, in alternate embodiments, additional or alternative components or sections could be provided. The internal circuitry 24 can include, for example, a processor or controller 104, a codec 106 coupled to amplifiers 108, 110 which are connected to a microphone 112 and a speaker or sound transducer 114, a SIM card reader 116 adapted to removably receive a SIM card 118, a memory card reader 120 adapted to removably receive a memory card 122, and a memory 124, as well as software programming. The user input 28 includes a first selector device 30 and a separate second selector device 32. The selector devices 30, 32 are coupled to the internal circuitry 24 and are adapted to be actuated by a user to control features of the device 14 and manually input information by the user into the device. Additional user input devices could also be provided. It should be noted that this is merely an example of some components. The invention could be practiced with any suitable structure and components as understood from reading of this description in its entirety.

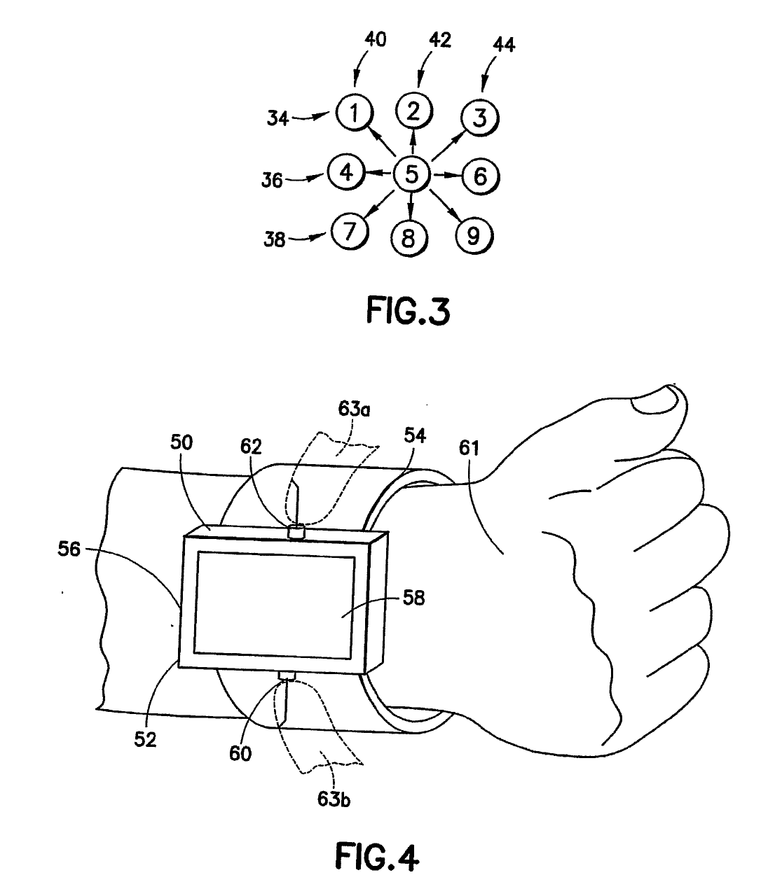

The first selector device 30 in this embodiment comprises a pointing device, such as a joystick, or a trackball, or a touch screen, or a multi-directional key, for example. Preferably the first selector device 30 is separate from the display 22. However, in a touch screen type of embodiment the first selector device 30 could include the display. Referring also to FIG. 3, the first selector device 30 is adapted to be actuated by a user to one of preferably at least nine position settings symbolized by the numbers 1-9 in FIG. 3. The nine position settings are generally arranged in three rows 34, 36, 38 and three columns 40, 42, 44. As seen, in this embodiment the position settings are not perfectly aligned in each row and column. The software and internal circuitry is adapted to assign a selectable value or data value for each of the position settings. This value can change depending upon a particular mode of operation of the device.

In a first mode of operation, the selectable values of the position settings are as follows:

| Position Setting | Selectable Value |
|---|---|
| 1 | 1 |
| 2 | 2 |
| 3 | 3 |
| 4 | 4 |
| 5 | 5 or 0 |
| | (depressed) |
| 6 | 6 |
| 7 | 7 |
| 8 | 8 |
| 9 | 9 |

In a preferred embodiment, the first selector device 30 can also be depressed at the middle position setting or 5 position setting to provide a selectable value of “0” (zero) as indicated above.

In another mode of operation, the selectable values for the position settings can comprise alphabetic characters. In a preferred embodiment, the alphabetic characters are related to the same position settings of corresponding numbers as laid out in a telephone keypad. For example, in an ITU-T keypad as follows:

| Position | |
|---|---|
| Setting | Selectable Value |
| 1 | |
| 2 | A or B or C |
| 3 | D or E or F |
| 4 | G or H or I |
| 5 | J or K or L |
| 6 | M or N or O |
| 7 | P or Q or R or S |
| 8 | T or U or S |
| 9 | W or X or Y or Z |

The letters could also include lower case letters; not merely upper case letters. However, any suitable layout could be provided including North American Classic, UK Classic, Mobile Phone Keypad 1, Australia (Formerly Austel Standard), Mobile Phone Keypad (European) or Mobile phone Keypad 111 (European) for example. For example, in the Mobile Phone Keypad 11 (European) and Mobile phone Keypad 111 (European) keypads, the number “5” key has the alphabetic characters “M’, “N”, and “0”. Although the invention has been described with reference to conventional telephone keypad emulation, features of the invention could be used to emulate other types of keypads or data input devices, for example “qwerty”. Thus, the first selection device could select from any set of virtual keys, and the second selector device or actuator would imitate pressing the selected key. Thus, an identification of a virtual key is provided with a first device, and an actuation of that virtual key is provided with the second separate device; regardless of the keypad or input device being imitated or emulated.

Movement of the first selector device 30 to one of the position settings does not select the corresponding selectable value for that position setting. Instead, movement of the first selector device 30 to one of the position settings merely identifies the corresponding selectable value for that position setting for possible selection when the user subsequently actuates the second selector device 32. This is illustrated in the flow diagram shown in FIG. 7. As indicated by block 100, a user moves the position sensor or first device 30 to one of a plurality of position settings; such as one of the nine or ten position settings noted above for example. This identifies a virtual key. As indicated by block 102, the user can then actuate the separate selection actuator or second device 32. This results in actuation of the identified virtual key.

The second selector device 32 preferably comprises a selection actuator, such as a depressible button or key for example. The second selector device 32 is coupled to the electronic circuitry 24 allow a user to select the selectable value identified by the position setting/of the first selector device 30. In this embodiment, the selectable value of a position setting of the first selector device 30 is only selected when the selection actuator of the second selector device 32 is actuated by the user while the first selector device is at that position setting. For example, in the first mode of operation, if the first selector device 30 is moved to the position setting 3, the number “3” is selected when the user actuates the second selector device 32. As another example, in a second mode of operation, if the first selector device 30 is moved to the position setting 3, the letters “D” or “E” or “F” can be selected when the user actuates the second selector device 32. The actual letter selected could be determined, for example, based upon how many times the second selector device 32 is actuated. For example, if actuated once the letter “D” is selected, and if actuated twice the letter “E” is selected, and if actuated three times the letter “F” is selected. Similar different alphabet selection techniques are known in the telephone handset technology with use of twelve key keypads, including scrolling through capitalized letters and lower case letters.

With the invention, text input into a mobile phone, PDA or wearable device can be provided. The invention can be used in new types of mobile devices that do not have space for an old style keypad, or for which an old style keypad would not fit for the device's design.

The invention describes a method to emulate the “ITU-T keypad”, or other similar telephone keypads, by using a combination of a device capable of separating 8 or 9 (ninth being the select) different directions or positions, and one separate button. The first device can be, for example, a digital or analog joystick, touch screen, capacitive sensor, acceleration sensor, gyro, compass, etc. An “ITU-T keypad” is the numeric key area that is familiar to users from most of the phones on the market. The pointing device of the invention can be used to identify the desired virtual ITU-T button according to the familiar directions of how they would be mapped in the ITU-T keypad, and then the separate button 32 is pressed to represent the pressing of the “virtual key” that was selected by pointing with the joystick 30. Thus the invention is not merely a mapping of the keys to the joystick directions, but a totally new kind of usage paradigm by separating the human's writing action into two different parts: selecting a key (position setting), and pressing an actuator for selecting that key.

As the actions are separated, the user can find the desired direction of turning before pressing the virtual button with the separate second button. This significantly reduces the amount of mistakes compared to a situation where the same pointing device would give a character out of every direction where the user happens to turn it when searching the correct letter. Thus, the direction detection method need not to be very high quality and/or physically very big. Because the direction detection method does not need to be very high quality, the components used to form the apparatus do not need to be expensive. Additionally, the separate clicking button 32 enables the use of an analog pointing device, such as a touch screen or acceleration sensor, etc, to select the letters and numbers, and still get the complete ITU-T usage feeling with the separate clicking button.

Also, the invention enables a “double-action” function. The virtual button (0-9 or A-Z) which the user is going to press is identified from the pointing device direction before the virtual button is actually pressed (when the second separate button is actuated). This allows, for example, showing the identified virtual button (or the character/number about to be selected) on the phone's screen 22, so that the user sees if the correct virtual button is going to be pressed. This can minimized wrong character/number entry.

The virtual twelve button “ITU-T keypad” is imitated by a two-phase method. In a first step, the first device 30, such as a joystick, is turned to the direction according the placement of a specific button in old style keypad. (This acts also as phase 1 for the “double-action” function.) In a second separate step, the separate “writing button” 32 is pressed as many times as the user would have pressed the actual key in the old style keypad. By repeating these steps, one can write just as he/she was writing using an ITU-T keypad. Every time the user goes from step 2 back to step 1, the previous character is automatically fixed and the next “virtual button” can be identified by the pointing device. Double letters can be differentiated, for example, by moving the user's finger on the pointing device to some other direction and back, or by waiting a bit similar to the old keypad.

These steps cover all the number keys (and according letters) from 0 to 9. The rest of the ITU-T keyboard (# and *) can be used, added to the symbols, for some other functions too, like a special character menu and mode switching between alphabetic/numbers. This is not a problem since they are not needed so often; most frequently needed punctuation marks are familiarly under “1”-key. For rarely needed symbols, the process can go just like in current mobile phone user interfaces (UI): the *-button (or soft key, etc.) can open a menu from where the user can get the desired symbol by navigating with the pointing device. The same goes with the alpha/number (#) key, it can be a softkey, menu item, or a long press of the “writing button” 32. One important key is naturally the backspace key. It's function is probably most reasonable to be left for the soft key or a separate C-key, just like it has been done for many years in all ITU-devices. However, for a system providing an input system other than emulating a telephone keypad, one of the position settings could be designated as a virtual backspace key. Likewise, for a system providing an input system other than emulating a telephone keypad, one of the position settings could be designated as a virtual soft key, or virtual “*” key or virtual “#” key, or virtual written text key(s) or common telephone symbol control key(s), such as “!” or “:)” or “:(” or [symbol] or [symbol] just as some examples.

With the invention, advantages can include, for example:
Intuitive use of the devices 30, 32 for the people familiar with an ITU-T keypad (most people). A correct letter is reached following a same thought pattern as text input using a ITU-T keypad, but merely pointing with the pointing device towards the direction of the desired key and then depressing a separate button as many times as needed.
user does not have to move his/her fingers away from the pointing device and the other button. This can provide fast writing (data entry).
Multiple implementations are possible which all could use the same usage paradigm.
A “double-action” methodology can be provided. An application (software) knows what the user is going to do next, before he/she actually does it, thus enabling the device 14 to make various helpful things with this information (for example showing the “value” on the screen before the user actually selects that value by actuating the second device 32).
Tactile feedback can be provided from the writing button 32 which can be just as good as when using normal keypad (such as a keypad having deflectable domes). There is no need for other feedback generation, and the user does not need to look at the display to realize that data entry has occurred.
The invention can be inexpensive to implement, using any standard digital or analog joystick found in almost any current phone or media device, and a few lines of coding would need to be written.

Referring also to FIG. 4, another embodiment of the invention is shown. In this embodiment the portable electronic device comprises a wrist device 50 adapted to be worn by the user, such as on an arm near a wrist 61. The device is preferably a mobile phone, but could comprise any suitable type of communications device. The device 50 comprises a main unit 52 and a wrist strap 54. Most of the electronics are in the main unit 52, but could extend into the wrist strap, such as the antenna for example. Another portion of the mobile phone could be carried by the user, such as in a pocket or briefcase, and be linked by a wireless link to the device 50.

The main unit 52 preferably comprises a frame 56, a display 58, a pointing device 60 and a writing button 62. In this embodiment the pointing device 60 is located on an opposite side of the frame 56 from the writing button 62. This enables the user to actuate the two devices 60, 62 with different fingers 63a, 63b of a same hand, such as similar to a pinching grasp with the thumb 63b operating one device and another finger 63a operating the other device. Thus, one handed data entry can be provided with the invention.

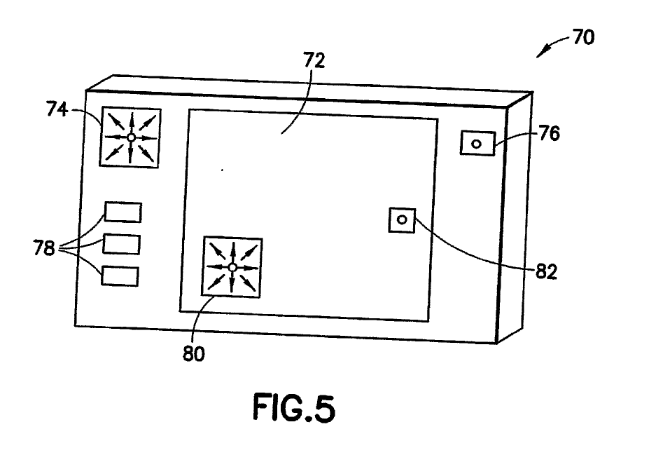

FIG. 5 shows another embodiment of the invention. In this embodiment the portable electronic device comprises a hand-held device 70 with a large screen 72 and some keys/buttons 74, 76, 78. In this embodiment, the screen 72 is a touch screen. The first button 74 comprises a multi-directional key which can be depressed into at least nine positions 1-9 shown in FIG. 3. Thus, the first button 74 forms a pointing device. The second key 76 forms the write button. The device 70 is also configured to provide two areas 80, 82 on the touch screen 72 to form a redundant pointing device and a redundant write button, respectively. A user can use either the first button 74 or the first area 80 to identify the data value 0-9 or A-Z. A user can use either the second button 76 or the second area 82 for selecting the identified value. This could be particularly useful for different users having different length fingers. Both users would find data entry ergonomically comfortable; the user with shorter fingers using 74 and 76, and the user with longer fingers using 80 and 82. Also, this allows other users to vary which buttons/areas they feel comfortable using, such as 74 with 82 or 80 with 76.

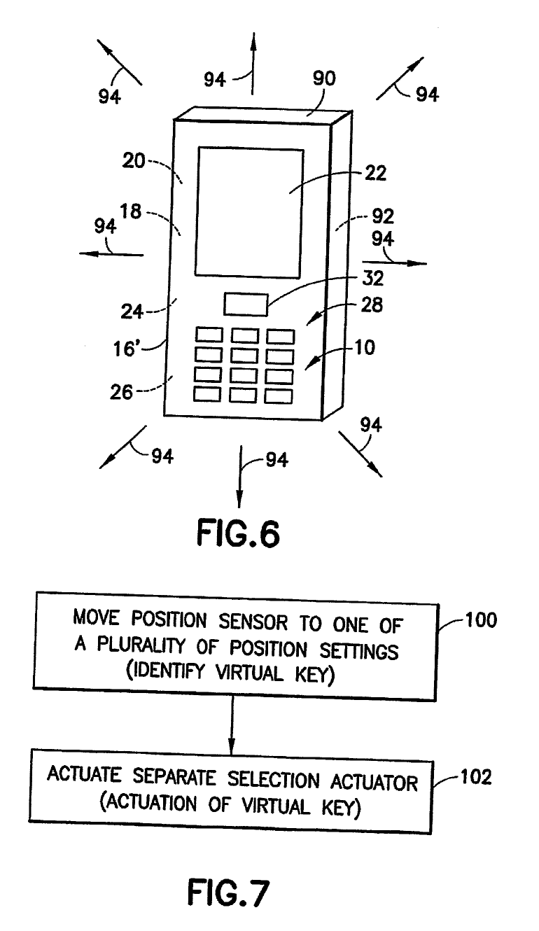

FIG. 6 shows a communication handset 90, such as a mobile phone, with an acceleration sensor or accelerometer 92 connected to its electronic circuitry 24. The phone 90 generally comprises a housing 16′, a transceiver 18, an antenna 20, a display 22, the internal circuitry 24, a battery 26, and a user input 28. However, in alternate embodiments, additional or alternative components or sections could be provided. The user input 28 includes a selector device 32 and a keypad 10. The accelerometer 92 is adapted to sense movement of the handset 90 in various directions 94. In this embodiment, the accelerometer 92 can sense movement in eight directions as shown. The accelerometer 92, thus, can be used as a first selector device to identify a value or range of values, such as 1-9 or A-Z, when the user moves the handset 90 in one of the directions 94. The user can then select the identified value by actuating the second selector device 32. Thus, a user can perform both operations with a single hand by merely moving or jerking the handset in different directions and pressing the button 32, such as with the user's thumb. The phone 90 could be the same as a conventional phone, but with the addition of accelerometer and suitable software. The button 32 could be a conventional button. With this invention, the user could use either the keypad 10 to input data and/or the multi-selector device 92/32 to input data.

It should be understood that the foregoing description is only illustrative of the invention. Various alternatives and modifications can be devised by those skilled in the art without departing from the invention. Accordingly, the invention is intended to embrace all such alternatives, modifications and variances which fall within the scope of the appended claims.

1. A telephone keypad emulation system for emulating data entry of a telephone keypad comprising:
a first selector device having a plurality of positions comprising a middle position setting; and
a second selector device comprising a selection actuator adapted to be actuated by a user, wherein the second selector device is spaced from the first selector device,
wherein, in a first mode of operation, the middle position setting of the first selector device comprises a selectable value, and wherein the selectable value of the position settings of the first selector device is only selected when the selection actuator of the second selector device is actuated by the user while the first selector device is at that position setting.

2. A telephone keypad emulation system as in claim 1 wherein the first selector device comprises:
a joystick, or
a trackball, or
a touch screen, or
a multi-directional key.

3-6. (canceled)

7. A telephone keypad emulation system as in claim 1 wherein the first selector device comprises an acceleration sensor.

8. A telephone keypad emulation system as in claim 1 wherein in a second mode of operation the middle position setting of the first selector device comprises a selectable value of “j” or “k” or “l”.

9. A telephone keypad emulation system as in claim 1 wherein in a second mode of operation the middle position setting of the first selector device comprises a selectable value of “m” or “n” or “o”.

10. A telephone keypad emulation system as in claim 1 wherein the middle position setting of the first selector device comprises the number “5” or a number “0” as the selectable value depending upon whether or not the direct selector device is depressed while at the middle position setting.

11. A telephone keypad emulation system as in claim 1 wherein, in the first mode of operation, two of the position settings oppositely lateral to the middle position setting comprises the selectable values of “4” and “6” respectively, three of the position settings upward from the middle position setting comprise the selectable values of “1”, “2” and “3” respectively, and three of the position settings downward from the middle position setting comprise selectable values of “7”, “8” and “9” respectively.

12. A telephone keypad emulation system as in claim 1 wherein the positions of the first selector device comprise at least nine position settings generally arranged in three rows and three columns.

13. A portable electronic device comprising:
a display;
electronic circuitry connected to the display; and
a telephone keypad emulation system as in claim 1 connected to the electronic circuitry.

14. A mobile telephone comprising:
a display;
electronic circuitry connected to the display, wherein the electronic circuitry comprises an antenna and a transceiver; and
a telephone keypad emulation system as in claim 1 connected to the electronic circuitry.

15. A program storage device readable by a machine, tangibly embodying a program of instructions executable by the machine for performing operations to emulate data entry of a telephone keypad, the operations comprising:
identifying a data value based upon movement of a first selector device by a user to one of a plurality of position settings; and
subsequently selecting the data value of the position setting and entering the data value into a memory based upon actuation of a spaced second selector device by the user while the first selector device is at the position setting,
wherein in a first mode of operation the data values of the position settings comprise numbers 1-9.

16. A method of emulating data entry of a telephone keypad with a directional position sensor comprising:
moving the directional position sensor to one of a plurality of settings; and
actuating a selection actuator by a user to select a data value corresponding to the setting of the directional position sensor, wherein the selection actuator is spaced from the directional position sensor.

17. A method as in claim 16 wherein, in a first mode of operation, two of the settings oppositely lateral to a middle setting comprise the data values of “4” and “6” respectively, three of the settings upward from the middle setting comprise the data values of “1”, “2” and “3” respectively, and three of the settings downward from the middle setting comprise data values of “7”, “8” and “9” respectively.

18. A method as in claim 16 wherein the directional position sensor comprises a joystick, and wherein moving the directional position sensor comprises moving the joystick to one of the settings.

19. A method as in claim 16 wherein the directional position sensor comprises a trackball, and wherein moving the directional position sensor comprises moving the trackball to move a display marker on a display to one of the settings.

20. A method as in claim 16 wherein the directional position sensor comprises a touch screen, and wherein moving the directional position sensor comprises a user contacting the touch screen to move a display marker on a display to one of the settings.

21. A method as in claim 16 wherein the directional position sensor comprises a multi-directional key, and wherein moving the directional position sensor comprises moving the multi-directional key to move a display marker on a display to one of the settings.

22. A method as in claim 16 wherein the directional position sensor comprises a multi-directional key, and wherein moving the directional position sensor comprises moving the multi-directional key to one of the settings.

23. A method as in claim 16 wherein the directional position sensor comprises a pointing device, and wherein moving the directional position sensor comprises moving the pointing device to move a display marker on a display to one of the settings.

24. A method as in claim 16 wherein moving the directional position sensor comprises depressing the directional position sensor while at a middle setting to establish a number “0” as the data value for the directional position sensor.

25. (canceled)
